(19) United States
(12) Patent Application Publication
(10) Pub. No.: US 2023/0017975 A1
(43) Pub. Date: Jan. 19, 2023

(54) DEVICE FOR THERMAL REGULATION OF AT LEAST ONE ELECTRICAL COMPONENT

(71) Applicant: Valeo Systemes Thermiques, La Verriere (FR)

(72) Inventors: Thibaut PERRIN, La Verriere (FR); Mohamed IBRAHIMI, La Verriere (FR)

(73) Assignee: Valeo Systemes Thermiques, La Verriere (FR)

(21) Appl. No.: 17/783,281

(22) PCT Filed: Dec. 11, 2020
(86) PCT No.: PCT/FR2020/052399

§ 371 Date: Jun. 8, 2022

(30) Foreign Application Priority Data
Dec. 12, 2019 (FR) FR1914323

(51) Int. Cl. H05K 7/20; H01M 10/613; H01M 10/6568; H01M 10/6556; H01M 50/276; H01M 50/278; H01M 50/28; H01M 50/224; H01M 50/222; H01M 50/227; H01M 50/229

(52) U.S. Cl. CPC H05K 7/20327; H05K 7/20345; H01M 10/613; H01M 10/6568; H01M 10/6556; H01M 50/276; H01M 50/278; H01M 50/28; H01M 50/224; H01M 50/222; H01M 50/227; H01M 50/229; H01M 2220/20

(57) ABSTRACT

Thermal regulation device intended for at least one electrical component whose temperature must be regulated, the thermal regulation device including at last a housing, a cover affixed to said housing and a first circuit, configured to allow circulation of a dielectric fluid. The housing includes at least a plurality of lateral walls delimiting an internal volume of the housing in which at least the electrical component extends. The first circuit includes at least one dielectric fluid supply duct formed between the housing and the lid, at least one of the lateral walls and/or the bottom wall having at least one orifice for spraying the dielectric fluid into the internal volume, which is fluidically connected at least to the supply duct.

### CROSS-REFERENCE TO RELATED APPLICATIONS

This application is filed under 35 U.S.C. § 371 U.S. National Phase of International Application No. PCT/FR2020/052399 filed Dec. 11, 2020 (published as WO2021116628), which claims priority benefit to French application No. 1914323 filed on Dec. 12, 2019, the disclosures of which are herein incorporated by reference in their entirety.

### TECHNICAL FIELD

The present invention is in the field of devices for thermal regulation of at least one electrical or electronic component which can heat up, and in particular it concerns a device for thermal regulation of electronic systems comprising components of this type.

### BACKGROUND OF THE INVENTION

The electronic systems to which the present invention can relate can consist both of computer servers and electrical energy storage systems, in particular battery elements, for motor vehicles.

In the field of motor vehicles, thermal regulation devices make it possible to modify a temperature of an electrical energy storage system, both when starting the vehicle in cold weather, by increasing its temperature for example, and when travelling or during an operation of recharging of said system, by decreasing the temperature of the battery elements, which tend to heat up when they are being used.

In general, devices of this type for thermal regulation of electrical energy storage systems use heat exchangers. The different battery elements of an electrical energy storage system can in particular be cooled by means of a cold plate in the interior of which a cooling fluid circulates, the plate being in contact with the battery elements to be cooled. It has been found that heat exchangers of this type can lead to non-homogeneous cooling of the battery elements of a single electrical energy storage system, thus giving rise to a decrease in the global performance of said system. These thermal regulation devices also have high thermal resistance because of the thicknesses of material present between the cooling fluid and the battery elements.

In addition, the size of devices of this type is large, since they need sufficient clearance between the heat exchangers and the components, the temperature of which is to be regulated, which involves over-sizing the housing in which the electrical or electronic components are accommodated.

A plurality of devices are known for the purpose of providing a solution to these different problems.

In particular, devices are known for cooling electric battery elements of electric or hybrid cars, comprising a hermetically sealed housing in which the battery elements of the electrical energy storage system are partly immersed in a dielectric fluid. This therefore provides heat exchange between the battery elements and the dielectric fluid, a dielectric fluid tank being situated on the exterior of the housing, and connected to said housing, in order to permit the circulation of the dielectric fluid.

However, the immersion of the electric battery elements in a fluid, in particular a dielectric fluid, does not permit homogeneous cooling of said elements. Document FR3077683 discloses a device for cooling battery elements which also comprises a hermetic housing, in which a dielectric fluid is placed, but wherein the dielectric fluid is sprayed onto the battery elements by a circuit and appropriate spraying means. When in contact with the battery elements which have heated up when they were operating, the sprayed dielectric fluid tends to vaporize, and the vapor is propagated in the housing, in particular along the walls which delimit the housing. Document FR3077683 discloses the presence of a condensation wall, comprising within it a cooling fluid circuit, the wall being a so-called condensation wall in that the temperature of this wall makes it possible to condense the vapor, such that the dielectric fluid regains a liquid form.

In this case also, in accordance with what has previously been described, a multiple problem of size occurs. The means which are necessary in order to permit the circulation then spraying of the dielectric fluid consist of a plurality of ducts which allow the circulation of the dielectric fluid in the interior of the housing, in particular passing through the walls of the housing in order to permit the entry and exit of the fluid into and out of the thermal regulation device. The assembly can also be complicated as a result of this multiplicity of ducts which must be secured relative to the walls of the housing, such that they do not come into contact with the electrical or electronic components before the fluid is sprayed.

The invention comes within this context, and its objective is to provide an alternative to the known thermal regulation devices, in particular in their application to electrical storage devices such as motor vehicle batteries, which alternative, inter alia, makes it possible to eliminate the aforementioned problems.

### BRIEF SUMMARY OF THE INVENTION

In this context, the present invention concerns a thermal regulation device which is designed for at least one electrical or electronic component, the temperature of which must be regulated, the thermal regulation device comprising at least one housing which is open on at least one side, a cover configured to close the housing on the at least one side, the housing comprising walls including at least a plurality of lateral walls connected by at least one base wall, said walls delimiting an inner volume of the housing in which at least the electronic component extends, the device also comprising a first circuit, which is configured to permit the circulation of the dielectric fluid, characterized in that the device comprises a lid which is added onto the housing, and in that the first circuit comprises at least one dielectric fluid supply duct formed between the housing and the lid, at least one of the lateral walls and/or the base wall comprising at least one orifice for spraying the dielectric fluid into the inner volume, which is fluidly connected to at least the supply duct.

By convention, throughout the present document, the term “longitudinal” applies to the direction of a main dimension of the housing of the thermal regulation device connecting two opposite lateral walls, the term “transverse” applies to a direction which is substantially perpendicular to the longitudinal direction, and joins to one another two other lateral walls of the housing, and the term “vertical” designates the direction perpendicular to both the longitudinal direction and the transverse direction, substantially perpendicular to the base wall of said housing.

“Duct” thus means a space for circulation of the dielectric fluid which is delimited firstly by one of the base or lateral walls of the housing, and secondly by the lid. Advantageously, the sealing of at least the supply duct can be carried out by welding or by gluing. Additionally, the supply duct can be equipped with at least one sealing unit, such as a seal.

The lid is added onto the housing, and can be kept integral therewith by welding. Advantageously, the lid can have a form which is at least partly complementary with that of the housing.

According to one characteristic, the lid has a structure in the form of a “U”, with a base and two lateral sections projecting from said base, the base being designed to extend facing the base wall of the housing, and the lateral sections extending facing two opposite lateral walls of the housing.

According to a characteristic of the invention, the base is added onto an outer face of the housing, opposite the inner volume delimited by the walls of the housing.

According to a characteristic of the invention, the lid comprises at least one primary trough participating in forming the at least one supply duct.

In particular, at least the primary trough and the secondary trough can extend into a plurality of base or lateral walls of the lid. The at least one primary trough and/or the at least one secondary trough can, for example, be obtained by thermoforming or by stamping.

According to a characteristic of the invention, at least one of the walls of the housing comprises a plurality of spray orifices, positioned in series such as to form a row for spraying of the dielectric fluid.

According to a characteristic of the invention, each spray orifice can be equipped with a nozzle for spraying the dielectric fluid.

According to the invention the spraying row can be positioned in a recess of said wall of the housing, such as to form a projection of the wall towards the interior of the housing, said recess being configured to form at least one distribution manifold for the dielectric fluid.

“Distribution manifold” means a defined circulation volume of the dielectric fluid which is delimited firstly by the lid, and secondly by the housing, and is configured to supply with dielectric fluid the plurality of spray orifices which constitute the at least one spraying row. In other words, the distribution manifold is fluidly connected to at least one supply duct and to the plurality of spray orifices of the at least one spraying row. By way of example, the recess which forms the distribution manifold can be produced by thermoforming or by stamping.

According to the invention, the thermal regulation device can comprise a plurality of distribution manifolds, at least two distribution manifolds being positioned in opposite lateral walls of the housing, said two distribution manifolds being fluidly connected by the supply duct.

Alternatively or in addition, a single lateral wall can comprise a plurality of distribution manifolds, said manifolds being by way of example superimposed on one another in a vertical direction which is substantially perpendicular to the base wall and to the main direction of the thermal regulation device. The supply duct can then advantageously extend in said lateral wall, such as to supply with dielectric fluid the plurality of distribution manifolds contained in this same lateral wall.

In addition, the thermal regulation device can be configured to comprise at least one spraying row positioned in the base wall and fluidly connected to the supply duct.

According to a characteristic of the invention, the first circuit comprises at least one duct for discharge of the dielectric fluid, formed between the housing and the lid, the base wall being able to comprise at least one perforation which is fluidly connected to at least the duct for discharge of the dielectric fluid.

Similarly to the supply duct, the discharge duct consists of a space for circulation of the dielectric fluid, which is delimited firstly by one of the walls of the housing, and secondly by the lid. In particular, the supply duct and the discharge duct are distinct. The lid can comprise a secondary trough which participates in forming the at least one discharge duct.

In other words, said perforation connects the inner volume fluidly to the at least one discharge duct. Advantageously, the thermal regulation device can comprise a plurality of perforations. Said perforations can for example have circular or also elongate forms, and can be arranged in series in the base wall.

The thermal regulation device comprises at least one entry mouth and/at least one exit mouth for the dielectric fluid in the thermal regulation device. In particular, the at least one entry mouth is at least fluidly connected to the supply duct, whereas the at least one exit mouth is at least fluidly connected to the discharge duct.

According to the invention, the lid comprises at least one cavity for recuperation of the dielectric fluid, the recuperation cavity being positioned facing at least the perforation in the direction defined by the vertical axis which is substantially perpendicular to the base wall, and the at least one discharge duct extends at least between the recuperation cavity and the at least one exit mouth for the dielectric fluid.

In other words, the dielectric fluid can be discharged from the inner volume of the thermal regulation device by circulating in succession through the at least one perforation, then in the at least one recuperation cavity, and the at least one discharge duct, before passing through the at least one exit mouth towards the exterior of the thermal regulation device.

According to the invention, the lid can comprise a plurality of recuperation cavities, the recuperation cavity, hereinafter known as the first cavity, and a second cavity, being arranged on both sides of the primary trough.

In particular, the first cavity can be connected to the discharge duct, hereinafter known as the first discharge duct, and to the exit mouth, hereinafter known as the first exit mouth, whereas the second cavity is connected to a second discharge duct and to a second exit mouth. Alternatively, the first cavity and the second cavity can be fluidly connected to the same discharge duct.

According to a characteristic of the invention, the housing and the lid can be made of a composite plastic material which is resistant to heat.

In particular, the material can consist of a thermoplastic which is consolidated with carbon fibers or aluminum fibers. Advantageously, the lid can be over-molded then welded or secured by means of at least one securing device on the housing.

According to the invention, the thermal regulation device comprises at least one second circuit which is configured to permit the circulation of a cooling fluid, at least one of the lateral walls of the housing comprising an entry hole and/or an exit hole for the cooling fluid in the second circuit.

By way of example, the cooling fluid can be glycoled water, or other coolant liquids of the type such as R134a or 1234yf. It should be noted that, in the present invention, the first circuit and the second circuit are distinct, such that the dielectric fluid which circulates in the first circuit, and the cooling fluid which circulates in the second circuit, are not mixed.

The thermal regulation device can comprise at least one plate incorporating the second circuit at least partly.

In particular the plate, which acts as a cold plate, is then configured so as to implement at least one heat exchange between the cooling fluid circulating in the second circuit and the dielectric fluid circulating in the first circuit. By way of example, the plate can be configured to act at least as a condenser for the dielectric fluid. The plate can be connected directly to at least the entry hole and/or the exit hole for the coolant fluid, or, alternatively, the plate can be connected to at least one of said holes by means of at least one connection unit, such as a connection column.

According to the invention, the thermal regulation device can comprise a plurality of electrical or electronic components, the temperature of which must be regulated, the plates being interposed between at least one first component and one second component.

Advantageously, the thermal regulation device can comprise a plurality of cold plates, which are configured to comprise at least part of the second circuit, and to permit the circulation of the cooling fluid.

Alternatively, the cold plate through which the second circuit passes can be formed directly by one of the walls of the housing and/or by the cover.

The present invention also concerns a thermal regulation system comprising at least the thermal regulation device as previously described, at least one unit for putting dielectric fluid into circulation in the first circuit, and at least one device for putting cooling fluid into circulation in the second circuit.

Said unit and device for putting into circulation, respectively of the dielectric fluid and the cooling fluid, can be pumps. The thermal regulation system comprises at least a plurality of connection pipes which are configured to connect the unit for putting into circulation to the entry mouth and/or the exit mouth for the dielectric fluid, or to connect the device for putting into circulation to the entry hole and/or the exit hole for the cooling fluid.

Advantageously, the thermal regulation system can comprise at least one joining piece which is positioned at the entry mouth and/or at least the exit mouth, and is configured to cooperate with at least one of the connection pipes.

### BRIEF DESCRIPTION OF THE DRAWINGS

Other characteristics, details and advantages of the invention will become more apparent from reading the following description on the one hand, and from a plurality of embodiments provided by way of non-limiting indication with reference to the appended schematic drawings on the other hand, in which:

FIG. 1 represents a thermal regulation system comprising at least one regulation device according to the invention;

FIG. 2 represents a view in perspective of the thermal regulation device, assembled, when it is without its cover;

FIG. 3 represents an exploded view in perspective of a housing and a lid of the thermal regulation device as illustrated in FIG. 2;

FIG. 4 represents a view in perspective of the housing and the lid of the thermal regulation device assembled, in which the lid is shown in transparency;

FIG. 5 is a view in cross-section, provided along a first longitudinal plane, of the thermal regulation device as illustrated in FIG. 2;

FIG. 6 is a view in cross-section, provided along a second longitudinal plane, of the thermal regulation device as illustrated in FIG. 2; and

FIG. 7 is a view in cross-section, provided along a transverse plane, of the thermal regulation device as illustrated in FIG. 2.

### DETAILED DESCRIPTION OF THE INVENTION

It should firstly be noted that the figures describe the invention in detail in order to implement the invention, and it will be appreciated that said figures can be used to define the invention better if applicable.

In addition, with reference to the orientations and directions previously defined, the longitudinal direction will be represented by the axis Ox, whereas the axes Oy and Oz will represent respectively the vertical and transverse directions. These axes defined together a trihedron xyz represented in the figures which require it. Within this frame of reference, the terms “top” or “upper” will be indicated by the positive direction of the axis Oy, the terms “bottom” or “lower” being indicated by the negative direction of this same axis Oy.

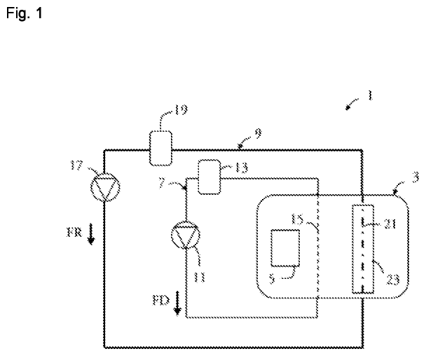

FIG. 1 represents schematically a thermal regulation system 1 comprising at least one thermal regulation device 3 associated with an electrical storage device, comprising one or a plurality of electrical or electronic components 5, the temperature of which must be regulated, for example decreased.

The thermal regulation system 1 comprises a first loop 7 of dielectric fluid (FD) and a second loop 9 of cooling fluid (FR).

The first loop 7 comprises at least one unit 11 for putting dielectric fluid into circulation, such as a pump, and in this case it comprises a storage tank 13 for said fluid. Also, the first loop 7 comprises at least one first circuit 15 permitting the circulation of the dielectric fluid, in this case represented schematically by a first broken line, said first circuit 15 being formed at least partly in the thermal regulation device 3.

The second loop 9 comprises at least one device 17 for putting the cooling fluid into circulation, such as a pump, and at least one tank 19 for storage of said fluid. In addition, the second loop 9 comprises at least one second circuit 21, permitting the circulation of the cooling fluid, and being formed at least partly in the thermal regulation device 3, and being represented by a second broken line. In particular, the second circuit 21 can extend at least partly in at least one plate 23, for example a cold plate 23, which is at least configured to act as a condenser.

Within the thermal regulation system 1, the thermal regulation device 3 is thus configured to implement at least one heat exchange between the dielectric fluid circulating in the first circuit 15 and the cooling fluid circulating in the second circuit 21, as will be described in greater detail hereinafter.

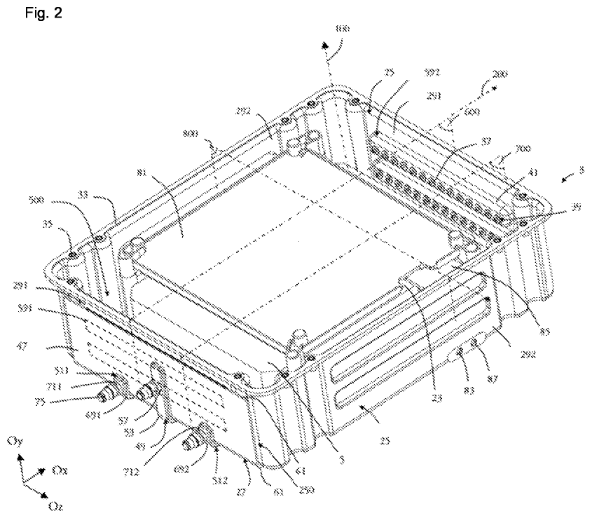

Reference is made initially to FIGS. 2 to 4 in order to describe more particularly the thermal regulation device 3, a cover of which, not represented, has been removed in order to show the interior arrangement in detail The thermal regulation device 3 comprises at least one housing 25 which is open on one side, the cover, which is configured to close the housing 25, and at least one lid 27 which is added onto said housing 25.

The thermal regulation device 3 also comprises at least the first circuit 15, which is configured to permit the circulation of a dielectric fluid, and the second circuit 21 which is configured to permit the circulation of a cooling fluid.

The dielectric fluid which can circulate in the first circuit 15 is selected according to its phase change temperatures. More particularly, the dielectric fluid must be characterized at least by a phase change temperature such that, this dielectric fluid, sprayed in the direction of the electrical or electronic components 5 in the liquid state, can be vaporized in contact with these components 5. Reference is thus made to diphase dielectric fluid, in that it has two different phases during its circulation in the thermal regulation device 3. By way of example, the dielectric fluid must have an evaporation temperature at atmospheric pressure which is higher than a temperature of approximately 32-34° C., and a condensation temperature which is lower than a temperature of approximately 29-31° C.

The cooling fluid which can circulate in the second circuit 21 can in particular consist of glycoled water, or other coolant fluids of the type such as R134a or 1234yf.

The housing 25 comprises a plurality of lateral walls, here primary lateral walls 291 and secondary lateral walls 292, which project from a common base wall 31, and extend in the vertical direction Oy defined by a vertical axis 100. It can be made of a composite and heat-resistant plastic material which, by way of example, can be consolidated with carbon fibers or aluminum fibers. The lateral walls and the base wall 31 of the housing 25 thus delimit an inner volume 500 of the thermal regulation device 3, in which there extends at least the electrical component 5, the temperature of which must be regulated.

In the example illustrated, the housing 25 has a substantially parallelepiped form, and comprises four lateral walls, with a main dimension of the housing 25 extending parallel to a longitudinal axis 200 of the longitudinal direction Ox. It is nevertheless understood that the form of the housing 25 is in no way limiting, and that it could for example comprise more lateral walls.

Upper borders 33 of the lateral walls are configured to cooperate with the cover. They comprise, for example, at least one fixation element 35 for securing said cover on the housing 25. By way of example, this cover can consist of a flat element, which is configured to cooperate with the housing 25, or of an element with a form and dimensions similar to those of the housing 25.

The housing 25 comprises a plurality of spray orifices 37 for spraying the dielectric fluid. Said spray orifices 37 consist of through-orifices, which in this case are circular, positioned in the lateral walls and/or in the base wall 31.

In the example illustrated, amongst the lateral walls there are distinguished primary lateral walls 291, orthogonal to the longitudinal axis 200 and opposite one another within the housing 25, which walls comprise a plurality of spray orifices 37, and secondary lateral walls 292, parallel to the longitudinal axis 200, which have no spray orifices 37. The spray orifices 37 are positioned in series in the transverse direction Oz such as to form two spraying rows 39 which are superimposed relative to one another in the vertical direction, and extend parallel to one another.

Advantageously, the spraying rows 39 are provided at recesses 41 of the primary lateral walls 291. The recesses 41 can be produced by thermoforming or by stamping, and form a substantially parallelepiped structure which extends towards the inner volume 500, with the different spray orifices 37 forming spraying rows 39 which are arranged at the base of said recesses 41, i.e. at a wall which extends in the interior of the inner volume 500.

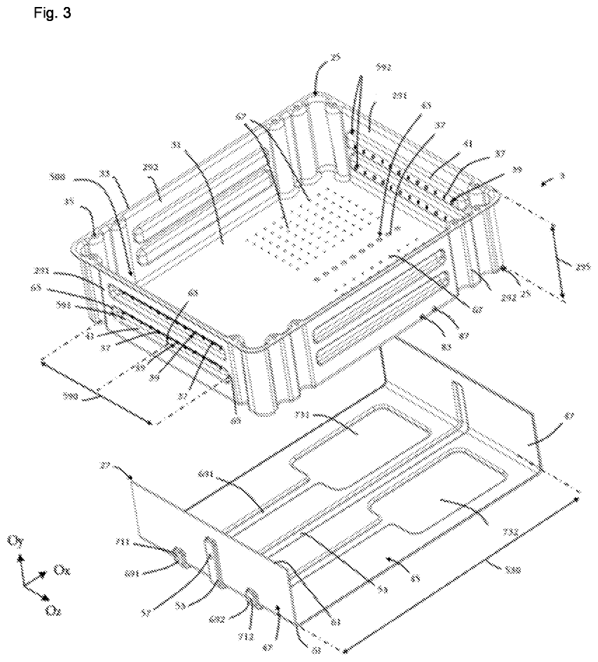

Also, according to the example illustrated, and as can be seen more particularly in FIG. 3, the thermal regulation device 3 comprises at least one additional spraying row 43 arranged in the base wall 31. It should be noted that, without departing from the context of the invention, the thermal regulation device 3 can be without said additional spraying row 43 at the base wall 31.

The lid 27 consists of an added-on part which is over-molded onto the housing 25. Thus, the lid 27 has a structure which is at least partly complementary to that of the housing 25. In the example illustrated, the lid 27 has a structure in the form of a “U”. It comprises a base 45 and two lateral sections 47 projecting from said base 45 in a direction which is substantially perpendicular to it. Similarly to the housing 25, the lid 27 can be made of a composite, heat-resistant plastic material which, by way of example, can be consolidated with carbon fibers or aluminum fibers.

When it is assembled on the housing 25, the lid 27 can be kept integral with said housing 25 by welding, gluing, or by means of at least one securing device, such as a screw-nut system. The base 45 of the lid 27 thus extends facing the base wall 31 of the housing 25, whereas the lateral sections 47 of the lid 27 in this case extend facing the primary lateral walls 291 of said housing 25.

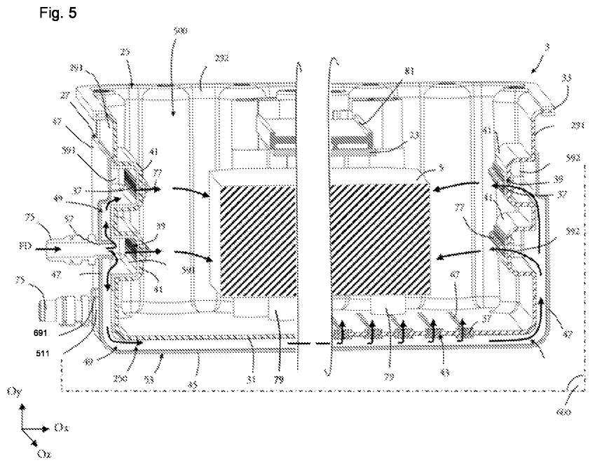

In the present invention, the lid 27 and the housing 25 are particularly configured such as to form a part of the first circuit 15, with an intermediate volume 250, contained between the lateral and/or the base 31 wall(s) of the housing 25 and the lid 27, forming at least one space for circulation of the dielectric fluid. This intermediate volume 250 will be described in greater detail hereinafter with reference to FIGS. 5 to 7.

In the thermal regulation device 3 illustrated, the first circuit 15 comprises a supply duct 49, which is configured to bring the dielectric fluid towards at least one of the spray orifices 37 for the dielectric fluid, and two discharge ducts, here a first discharge duct 511 and a second discharge duct 512. It should be noted that the number of supply 49 or discharge ducts is in no way limiting, and can be modified, such that, for example, the thermal regulation device 3 comprises a plurality of supply ducts 49, or, alternatively, such that it comprises a single discharge duct.

The supply duct 49 is formed between the housing 25 and the lid 27, in the intermediate volume 250. The lid 27 comprises at least one trough, known as the primary trough 53, which participates in forming said supply duct 49. The primary trough 53 consists of a recess which is provided in the lid 27, by stamping or thermoforming for example, and is configured to direct and limit the circulation of the dielectric fluid in the intermediate volume 250 of the thermal regulation device 3. The primary trough 53 illustrated extends along a longitudinal length 530 of the base 45 of the lid 27, in the longitudinal direction Ox, and partly in the lateral sections 47 of the lid 27, parallel to the vertical axis 100, such that, when the lid 27 and the housing 25 are assembled, the supply duct 49 extends along the primary lateral walls 291 and the base wall 31 of the housing 25.

At one of its lateral sections 47, known hereinafter as the first lateral section, the lid 27 comprises at least one entry mouth 57 for the dielectric fluid, which is fluidly connected to the supply duct 49 formed between the lid 27 and the housing 25. Thus, the dielectric fluid is brought into the thermal regulation device 3 via the entry mouth 57 which is positioned projecting from the lid 27, and can then circulate in the supply duct 49.

The supply duct 49 extends in the thermal regulation device 3, such as to connect the entry mouth 57 fluidly to at least one of the orifices 37 for spraying of the dielectric fluid, for the purpose of spraying of the dielectric fluid in the inner volume 500, in particular onto the electrical component 5. In particular, the primary trough 53 is positioned such as to extend at least partly facing at least one of the recesses 41 of the housing 25, comprising at least one of the spraying rows 39. In particular, when the housing 25 and the lid 27 are assembled, each of the recesses 41 forms a distribution manifold, in particular a primary distribution manifold 591 or secondary distribution manifold 592, for distribution of the dielectric fluid towards a plurality of spray orifices 37, for example one or a plurality of spraying rows 39, i.e. the recesses 41 form volumes for circulation and distribution of the dielectric fluid within the intermediate volume 250, such as to supply to spray orifices 37 which can be arranged spaced from the supply duct 49.

Advantageously, the thermal regulation device 3 can thus comprise one or a plurality of distribution manifolds in each of its opposite primary lateral walls 291. In the example illustrated, each of the primary lateral walls 291 comprises two distribution manifolds, each accommodating a spraying row 39 of spray orifices 37.

In particular, the primary trough 53 can extend perpendicularly to the at least one distribution manifold, with the primary trough 53 thus extending vertically over at least a portion of the vertical dimension 295 of the housing 25, measured along the vertical axis 100 between two opposite vertical ends 61 of one of the primary lateral walls 291, such as to supply the different distribution manifolds superimposed in a single primary lateral wall 291 with dielectric fluid.

In other words, it is notable that at the lateral walls of the housing 25, and thus the sections of the lid 27, the primary trough 53 extends substantially perpendicularly to each of the manifolds also formed in these areas. Thus, the supply duct 49 connects each of the distribution manifolds fluidly, and the intake of dielectric fluid into the housing 25 via an entry orifice formed in this supply duct 49 makes it possible to direct the dielectric fluid towards each of the manifolds, and thus each of the spray orifices 37.

In order to optimize and homogenize the distribution of the fluid in the distribution manifolds, and thus towards the different spray orifices 37, the supply duct 49 is particularly centered relative to at least one of the distribution manifolds, i.e. it extends facing a transverse middle 63 of the length 590 of at least one of said distribution manifolds, evaluated along the transverse axis, between two end edges 65 of said distribution manifold.

In order to ensure the discharge of the dielectric fluid sprayed into the inner volume 500, the thermal regulation device 3 comprises at least one perforation 67 and the discharge ducts.

The perforation 67 is positioned in the base wall 31 of the housing 25, and assures the fluid connection between the inner volume 500, delimited by the walls of the housing 25, and the intermediate volume 250, which extends between the lid 27 and the housing 25. Advantageously, the thermal regulation device 3 comprises a plurality of perforations 67.

In the example illustrated, the base wall 31 comprises two sub-assemblies of perforations 67 positioned on both sides of the additional spraying row 43, said perforations 67 being positioned in particular such as to be fluidly connected to at least one of the discharge ducts.

Similarly to the supply duct 49, the discharge ducts are formed between the housing 25 and the lid 27, in the intermediate volume 250 which thus comprises at least the supply duct 49, the distribution manifolds 39, and the discharge ducts. In the example illustrated, the lid 27 comprises a plurality of troughs, known as secondary troughs, here a first secondary trough 691 and a second secondary troughs 692, which participate in forming of said discharge ducts. The first secondary trough 691 participates in forming the first discharge duct 511, whereas the second secondary trough 692 participates in forming the second discharge duct 512. Like the primary trough 53, the secondary troughs consist of recesses which are provided in the lid 27, and are configured to direct and limit the circulation of the dielectric fluid in the intermediate volume 250 of the thermal regulation device 3, in particular in order to organize in a distinct manner the circulation of the dielectric fluid entering, i.e. which is designed to be sprayed in the inner volume 500, and the circulation of the dielectric fluid exiting, i.e. which is designed to be discharged from the thermal regulation device 3. The secondary troughs extend partly in the base 45 of the lid 27 and, as illustrated, can extend at least partly into at least one of the lateral sections 47 thereof.

The lid 27 comprises at least one exit mouth for the dielectric fluid, which is fluidly connected to at least one of the discharge ducts formed by the lid 27, and the housing 25 is configured to discharge the dielectric fluid to the exterior of the thermal regulation device 3. In this case, the lid 27 comprises two exit mouths for the dielectric fluid, i.e. a first exit mouth 711 and the second exit mouth 712, which are respectively fluidly connected to the first discharge duct 511 and to the second discharge duct 512.

In order to limit the size of the thermal regulation device 3, the exit mouths are, like the entry mouth 57, positioned in the first lateral section of the lid 27. It could however be envisaged to position at least one of the exit mouths in the opposite lateral section 47, or in the base 45 of the lid 27.

Also, in order to optimize the discharge of the dielectric fluid, the lid 27 comprises at least one recuperation cavity for recuperation of the dielectric fluid. The recuperation cavity consists of a recess with a transverse dimension larger than the transverse dimension of a corresponding discharge duct, this recuperation cavity being configured to receive the dielectric fluid which is obtained from the inner volume 500 and passes through the perforations 67. The recuperation cavity is part of the intermediate volume 250, and extends vertically facing at least one of the perforations 67 of the base wall 31 of the housing 25. It is fluidly connected to at least one of the discharge ducts, such that the dielectric fluid which passes through at least one of the perforations 67 is sent into the recuperation cavity, then to at least one of said discharge ducts.

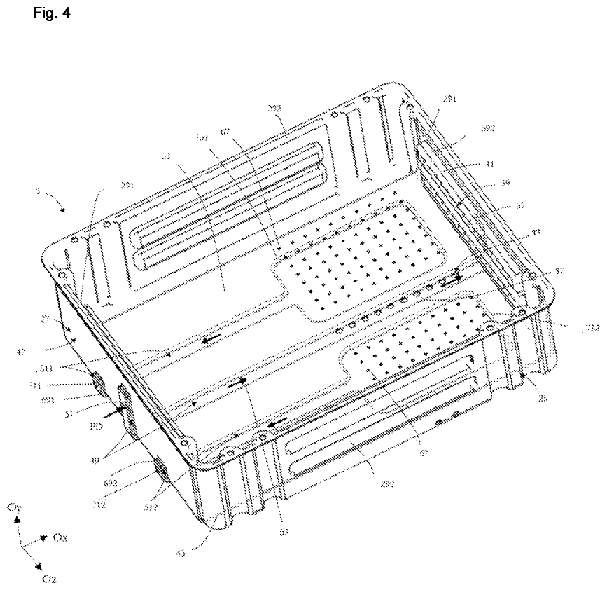

As can be seen in particular in FIGS. 3 and 4, the lid 27 comprises a plurality of recuperation cavities, known as a first cavity 731 and a second cavity 732. The first cavity 731 is positioned facing a first sub-assembly of perforations 67 of the housing 25. It is positioned in the lid 27, such that the first secondary trough 691 extends between the first cavity 731 and the first exit mouth 711. Similarly, the second cavity 732 is positioned facing a second sub-assembly of perforations 67 and is arranged in the lid 27 such that the second secondary trough 692 extends between said second cavity 732 and the second exit mouth 712 for the dielectric fluid.

The first cavity 731 and the second cavity 732 are, in the transverse direction, positioned on both sides of the primary trough 53 in the lid 27. Consequently, the first discharge duct 511 and the second discharge duct 512 are positioned on both sides of the supply duct 49, and the dielectric fluid entry mouth 57 is interposed between the different exit mouths for the dielectric fluid.

According to an alternative, not represented, at least one of the discharge ducts can be fluidly connected to a plurality of recuperation cavities.

FIGS. 5 to 7 represent different cross-sections of the thermal regulation device 3, making it possible to show in greater detail the relative arrangement of the components of said thermal regulation device 3, in particular within the inner volume 500 delimited by the housing 25, as well as the circulation of the dielectric fluid within said thermal regulation device 3.

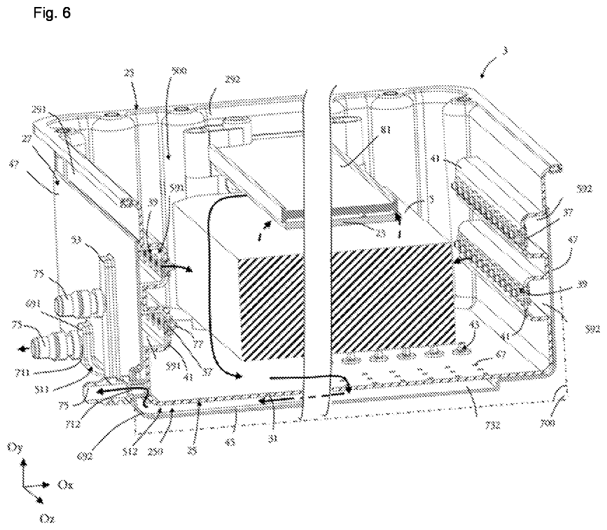

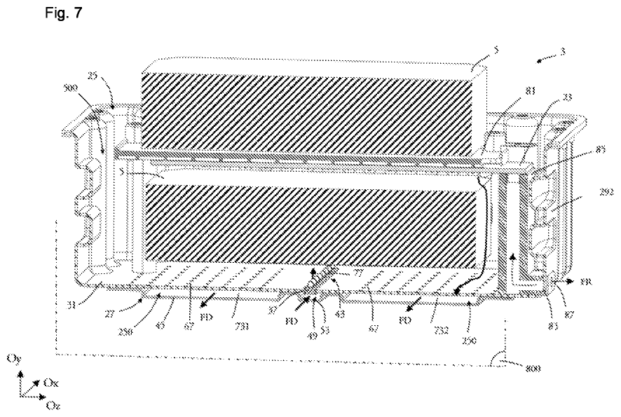

FIG. 5 and FIG. 6 represent longitudinal cross-sections of the thermal regulation device 3, provided respectively along a first longitudinal plane 600 and a second longitudinal plane 700, as illustrated in FIG. 2, with the first longitudinal plane 600 passing via the supply duct 49, and the second longitudinal plane 700 passing via the second discharge duct 512. FIG. 7 represents a transverse cross-section of the thermal regulation device 3 provided along a transverse plane 800 which passes via the first cavity 731 and via the second cavity 732 of the lid 27.

The dielectric fluid circulating in the first loop 7 of the thermal regulation system 1, in this case illustrated by the arrows (FD), is brought to the entry mouth 57 by at least one pipe of the thermal regulation system 1. Advantageously, the connection of the regulation device 3 in the thermal regulation system 1 can be provided, as illustrated, by means of at least one joining piece 75, which is configured to cooperate with the entry mouth 57 for the dielectric fluid, which entry mouth 57 is contained in the lid 27.

The dielectric fluid which passes through the entry mouth 57 is poured into the intermediate volume 250, between the first lateral section of the lid 27 and the lateral wall of the housing 25, and more particularly into the supply duct 49 of the intermediate volume 250. Advantageously, the sealing of at least the supply duct 49 come be provided by welding or by gluing. Alternatively, the supply duct 49 can be equipped with at least one sealing unit such as a seal, so as to separate the circulation of the dielectric fluid implemented in the supply duct 49 and in the discharge ducts.

Part of the dielectric fluid is sent to the distribution manifolds, here first distribution manifolds 591, defined by the recesses 41 which are contained in the primary lateral wall 291 positioned facing the entry mouth 57 for the dielectric fluid. The other part of the dielectric fluid is sent to distinct secondary distribution manifolds 592, which are delimited by recesses 41 contained in the primary lateral wall 291 longitudinally opposite the housing 25, by means of the supply duct 49 formed partly by the primary trough 53.

Thus, in each of the distribution manifolds, the dielectric fluid is distributed such as to supply to the different spray orifices 37. As illustrated, said spray orifices 37 can be equipped with spraying nozzles 77. Advantageously, said spraying nozzles 77 can have orientations which are variable relative to the electrical component 5 to be cooled, either within a single distribution manifold, or from one distribution manifold to another.

As previously described, when it is circulating along the supply duct 49, from the primary distribution manifolds 591 to the second redistribution manifolds 592, the dielectric fluid is also sprayed in the inner volume by means of the spray orifices 37 of the additional spraying row 43 contained in the base wall 31 of the housing 25. Advantageously, the spray orifices 37 of the additional spraying row 43 can be equipped with spraying nozzles 77 with orientation which is substantially identical or variable relative to one another.

The dielectric fluid is thus sprayed in liquid form in the inner volume 500. Part of this dielectric fluid comes into contact with the hot electrical or electronic component 5, and captures calories thereof. In particular, in the example illustrated, the electrical or electronic component 5 is positioned centrally within the inner volume 500, spaced from the base wall 31, such that the assembly of the different spraying rows 39, 43 can permit spraying of dielectric fluid towards said electrical or electronic component 5. In particular, this electrical or electronic component 5 is kept in position in the thermal regulation device 3 by at least one retention unit 79. An arrangement of this type contributes towards the cooling of the different lateral, upper and lower portions of the electrical or electronic component 5, and makes it possible to assure homogeneous cooling of said electrical or electronic component 5. Advantageously, and as can be seen in FIG. 7, the thermal regulation device 3 can accommodate, and assure the heat treatment of, a plurality of electrical or electronic components 5. As illustrated, these can then be superimposed vertically on one another, or, alternatively, they can be positioned in series within the inner volume 500.

The dielectric fluid which is sprayed onto the electrical or electronic component(s) 5, capturing the calories of the component(s) 5, is then evaporated in gaseous form in the inner volume 500, and comes into contact with the cold plate 23 acting as a condenser. In the example illustrated, the plate 23 is retained by a support 81 and/or at least one securing unit, such as a clip system. In particular, the cold plate 23 can be positioned on a plane substantially parallel to the base wall 31, at the approach to the electrical or electronic component 5, and above it. Also, with reference to FIG. 7, when the thermal regulation device 3 comprises a plurality of electrical or electronic components 5, the temperature of which must be regulated, the cold plate 23 can be positioned such as to be vertically interposed between at least a first electrical or electronic component 5 and a second electrical or electronic component 5.

As previously described, the cold plate 23 comprises at least part of the second circuit 21 in which the cooling fluid circulates. It permits implementation of heat exchange between the evaporated dielectric fluid and the cooling fluid, which is colder, circulating in the second circuit 21 contained in the plate 23. The dielectric fluid yields its calories to the cooling fluid, and is thus condensed. The liquid dielectric fluid, whether it is dielectric fluid sprayed by one of the spray nozzles 77, or dielectric fluid condensed by heat exchange with the cold plate 23, then falls to the base of the housing 25, onto the base wall 31. It passes through the plurality of perforations 67 contained in said base wall 31, and is poured into one of the recuperation cavities visible in FIGS. 6 and 7, formed partly by the lid 27. The liquid dielectric fluid is then sent to the discharge ducts, formed partly by the secondary troughs, and is then discharged from the thermal regulation device 3 via the exit mouths for the dielectric fluid, in order to be returned to the pipes of the first loop 7 of the thermal regulation system 1.

The thermal regulation device 3 according to the present invention thus advantageously permits, within the intermediate volume 250, circulation of the dielectric fluid in two opposite directions, i.e. a first for the purpose of supplying to the secondary distribution manifolds 592, and a second for the purpose of discharging the dielectric fluid.

In parallel with the circulation of the dielectric fluid, the cooling fluid is brought into the thermal regulation device 3 via an entry hole 83, and is brought into the second circuit 21 of the cold plate 23 by means of a first channel, not represented, of a connection unit, in this case of a connection column 85. As previously described, in the plate 23, the cooling fluid is heated by heat exchange with the dielectric fluid, and is then brought to an exit hole 87 of the thermal regulation device 3 by a second channel of the connection column 85, and is then discharged from the thermal regulation device 3.

It should be noted that, in the present invention, the entry 83 and exit 87 holes for the cooling fluid are arranged in one of the secondary lateral walls 292 of the housing 25, such as to be able to arrange the supply to at least the cold plate 23 as required, without however impeding the spraying of the dielectric fluid by the different spraying rows 39, or additional spraying row 43. In addition, according to the description given, the second circuit 21 is provided at least partly in a cold plate 23 which is formed distinctly from the walls of the housing 25, but it should be noted that, without departing from the context of the invention, this second circuit 21 could be produced in a wall of the housing 25 or in the cover which is provided to close the housing 25.

It is understood from reading the foregoing description that the present invention proposes a thermal regulation system 1 comprising at least one thermal regulation device 3 for thermal regulation of at least one electrical or electronic component 5, such as an electrical storage device. The thermal regulation device 3 comprises a housing 25 which is open on one side and closed by a cover as well as by an added-on lid 27, with the housing 25 and the lid 27 being configured to form at least one supply duct of a first dielectric fluid circuit 15. The thermal regulation device 3 can also comprise at least one discharge duct for said fluid formed between this same lid 27 and housing 25. The thermal regulation device 3 according to the present invention advantageously thus permits simplification of the circulation and spraying of the dielectric fluid onto the at least one electrical or electronic component 5 accommodated within the thermal regulation device 3.

The invention is, however, not limited to the means and configurations described and illustrated here, and it also encompasses any equivalent means or equivalent configuration and any technically workable combination of such means. In particular, the location of the spraying rows, their number, and the number of spray orifices or their form, can be modified without detracting from the invention, provided that the thermal regulation device ultimately fulfils the same functionalities as those described in the present document.

What is claimed is:

1. A thermal regulation device for at least one electrical or electronic component, the thermal regulation device comprising at least one housing which is open on at least one side and closable by a cover configured to, the at least one housing having walls including at least a plurality of lateral walls connected by at least one base wall, said walls delimiting an inner volume of the at least one housing in which the at least one electrical or electronic component extends, the thermal regulation device also including a first circuit configured to permit circulation of a dielectric fluid, wherein the thermal regulation device includes a lid which is added onto the at least one housing, and wherein the first circuit includes at least one dielectric fluid supply duct formed between the at least one housing and the lid, at least one of the walls of the at least one housing including at least one spray orifice for spraying the dielectric fluid into the inner volume, which is fluidly connected to the at least one dielectric fluid supply duct.

2. The thermal regulation device as claimed in claim 1, wherein the lid has a structure in the form of a “U”, with a base and two lateral sections projecting from said base, the base being designed to extend facing the at least one base wall of the at least one housing, and the lateral sections extending facing two opposite lateral walls of the at least one housing.

3. The thermal regulation device as claimed in claim 2, wherein the base is added onto an outer face of the at least one housing, opposite the inner volume delimited by the walls of the at least one housing.

4. The thermal regulation device as claimed in claim 1, wherein at least one of the walls of the at least one housing includes a plurality of spray orifices positioned in series, such as to form a spraying row for the dielectric fluid.

5. The thermal regulation device as claimed in claim 4, wherein the spraying row is positioned in a recess of said wall of the at least one housing such as to form a projection of the wall towards the interior of the at least one housing, said recess being configured to form at least one distribution manifold for the dielectric fluid.

6. The thermal regulation as claimed in claim 1, wherein the first circuit includes at least one discharge duct for the dielectric fluid formed between the at least one housing and the lid, the base wall including at least one perforation which is fluidly connected to at least the duct discharge duct for the dielectric fluid.

7. The thermal regulation device as claimed in claim 6, wherein the lid includes at least one recuperation cavity for the dielectric fluid positioned facing the at least one perforation in a direction which is defined by a vertical axis which is substantially perpendicular to the base wall, with the at least one discharge duct extending at least between the recuperation cavity and at least one exit mouth for the dielectric fluid.

8. The thermal regulation device as claimed in claim 1, wherein the at least one housing and the lid are made of a composite plastic material which is resistant to heat.

9. The thermal regulation device as claimed in claim 1, including at least one second circuit which is configured to permit circulation of a cooling fluid, at least one of the lateral walls of the at least one housing having an entry hole and an exit hole for the cooling fluid in the at least one second circuit.

10. A thermal regulation system including
at least one thermal regulation device for at least one electrical or electronic component, the thermal regulation device including at least one housing which is open on at least one side and closable by a cover, the at least one housing having walls including at least a plurality of lateral walls connected by at least one base wall, said walls delimiting an inner volume of the at least one housing in which the at least one electrical or electronic component extends, the thermal regulation device also including a first circuit configured to permit circulation of a dielectric fluid, wherein the thermal regulation device includes a lid which is added onto the at least one housing, and wherein the first circuit includes at least one dielectric fluid supply duct formed between the at least one housing and the lid, at least one of the walls of the at least one housing including at least one spray orifice for spraying the dielectric fluid into the inner volume, which is fluidly connected to the at least one dielectric fluid supply duct;
at least one second circuit which is configured to permit circulation of a cooling fluid, at least one of the lateral walls of the at least one housing having an entry hole and an exit hole for the cooling fluid in the at least one second circuit;
and at least one unit for putting the dielectric fluid into circulation in the first circuit and at least one device for putting cooling fluid into circulation in the second circuit.

11. The thermal regulation device as claimed in claim 1, including at least one second circuit which is configured to permit circulation of a cooling fluid, at least one of the lateral walls of the at least one housing having an entry hole or an exit hole for the cooling fluid in the second circuit.
